(19) United States
(12) Patent Application Publication
(10) Pub. No.: US 2007/0148368 A1
(43) Pub. Date: Jun. 28, 2007

(54) Apparatus for plasma treatment of dielectric bodies

(76) Inventors: Gregor Arnold, Bodenheim (DE); Stephan Behle, Hahnheim (DE); Matthias Bicker, Mainz (DE); Andreas Luttringhaus-Henkel, Darmstadt (DE)

Correspondence Address: M. Robert Kestenbaum, 11011 Bermuda Dunes NE, Albuquerque, NM, 87111, US

(21) Appl. No.: 11/527,110

(22) Filed: Sep. 25, 2006

Related U.S. Application Data
(62) Division of application No. 10/349,361, filed on Jan. 21, 2003.

(30) Foreign Application Priority Data
Jan. 23, 2002 (DE) 102 02 311.5

(51) Int. Cl. C23C 16/00; H05H 1/24

(52) U.S. Cl. 427/569; 427/255.5

(57) ABSTRACT

In order to allow a continuous production process for the plasma treatment of workpieces, an apparatus for plasma treatment of workpieces is provided which comprises a transport device and a plasma generating device which injects electromagnetic energy into an area of the apparatus during operation, in which the transport device carries the workpieces through the area continuously.

### CROSS-REFERENCES TO RELATED APPLICATIONS

This is a Divisional Application of U.S. patent application Ser. No. 10/349,361, which was filed on Jan. 21, 2003, and is still pending. The parent application U.S. patent application Ser. No. 10/349,361 claims priority of DE 102 02 311.5 filed Jan. 23, 2002.

### STATEMENT REGARDING FEDERALLY SPONSORED RESEARCH OR DEVELOPMENT

Not applicable.

### BACKGROUND OF THE INVENTION

The invention relates to an apparatus and a method for plasma treatment of dielectric bodies, in particular to an apparatus and a method for plasma coating or plasma conditioning of dielectric bodies.

Various chemical vapor phase deposition methods (CVD methods) are used, inter alia, to produce the layers.

In CVD methods, a layer is deposited by means of a gaseous reactive chemical compound in the vicinity of the workpiece that is to be treated, which chemical compound is ionized by the introduction of energy. The reaction products are precipitated on the surface of the workpiece and form a layer whose composition differs from the original materials, with the final reaction of the intermediate products from the vapor phase to the material of the layer generally taking place only on the surface of the workpiece. Since widely differing educts can be mixed with one another, CVD methods can be produced to produce a very wide range of layers with different chemical and physical characteristics. Both gaseous substances and substances which can be vaporized may be used as educts.

In detail, a distinction is drawn between thermal CVD methods and plasmaenhanced CVD methods (PECVD methods).

In the case of thermal CVD coating, the reaction of the educts is induced thermally, and this generally requires process temperatures between 600° C. and 1300° C. Owing to the relatively high substrate temperatures that are required, not all materials are suitable for coating by means of thermal CVD deposition.

In the case of PECVD deposition, on the other hand, a plasma is produced by ionization by means of external electromagnetic fields, so that the required process temperatures are lower. Coating temperatures which are between 500° C. and room temperature are normally used for this purpose.

Plasma coating systems that are configured as longitudinal feeds or circular feeds are used for the industrial production of thin layers on substrates. In these systems, electromagnetic fields are supplied individually to each workpiece to be coated via an individual electromagnetic supply, in order to produce the plasma. For example, this is done by placing a shroud over the workpiece, via which shroud the electromagnetic fields are injected.

However, this requires a complex system if the aim is to produce a continuous process sequence. For a continuous production process such as this, in which the workpieces are moved through the coating apparatus, the devices for supplying electromagnetic energy would also have to be moved with the moving workpieces. However, a continuous production process is particularly advantageous since it is relatively insensitive to process time fluctuations. This means, for example, that a longer coating duration will have less influence on the system scrap rate. Conversely, more bodies or workpieces can be coated in a given time, with the same coating duration, compared with a discontinuous process sequence.

### SUMMARY OF THE INVENTION

The present invention is therefore based on the object of providing an apparatus and a method which allow a continuous production process to be achieved for plasma coating of workpieces.

This object is achieved in a surprisingly simple manner by the apparatus for plasma treatment of workpieces comprising a transport device, and a plasma generating device that injects electromagnetic energy into an area of the apparatus during operation, wherein the transport device carries the workpieces through the area continuously. The object is also achieved by the method for plasma treatment of workpieces comprising the steps of production of an electromagnetic field within an area in order to produce a plasma within this area, treatment of a workpiece by means of the plasma that is produced by the electromagnetic field, distinguished by the workpiece being passed through the area continuously.

Thus, according to the invention, an apparatus for plasma treatment of workpieces is provided, which comprises a transport device and a plasma generating device which injects electromagnetic energy into an area of the apparatus during operation, in which the transport device carries the workpieces through the area continuously.

The area in which the plasma generating device injects electromagnetic energy and through which the workpieces are passed continuously is also referred to in the following text as the coating area. The expression plasma treatment should be understood as meaning not only PECVD coating but also plasma conditioning. Plasma conditioning is achieved, for example, in an oxygen atmosphere by which means the oxygen plasma results in oxygen radicals building up in the treated surface area, as a result of which the surface is conditioned for further process steps.

An advantage of the apparatus according to the invention over known systems which are in the form of longitudinal or circular feeds with individual coating chambers is that it is less sensitive to process time fluctuations. If, for example, workpieces are provided with a coating which requires a comparatively long coating duration, then the continuous processing procedure means that there is less influence on the scrap rate of the coating system. A higher throughput rate can thus likewise be achieved for the same coating duration, which means that the production process is more cost-efficient.

The plasma generating device for injecting the electromagnetic energy into the area of the apparatus preferably has at least one field applicator. The apparatus also has a source for producing electromagnetic energy, which source is connected to the field applicator so that the energy produced by the source can be transmitted to the field applicator and can be injected from it into the area for plasma production.

According to one embodiment, the workpieces are passed along a circular path through the apparatus by the transport device. This can be achieved, for example, by the transport device having a round running table on which the workpieces are placed.

However, the apparatus may likewise also be designed as a longitudinal feed system. In this case, the workpieces are passed along a linear path by the transport device.

Particularly for the circular feed embodiment of the apparatus according to the invention, the field applicator may have an antenna arrangement comprising two plates which are curved in a circular shape and are spaced apart in the radial direction. The plates thus form an antenna arrangement which, when an electrical AC voltage is supplied, produce an electrical alternating field which extends in the radial direction between the two plates. With a suitable gas atmosphere, the influence of the alternating field produces a plasma between the mutually facing surfaces of the two plates, through which the workpieces are then passed continuously by means of the transport device, for coating and/or for conditioning.

Parallel-arranged, flat plates are likewise also suitable for the production of an electromagnetic alternating field, in particular when using a longitudinal feed system.

The electromagnetic field which is produced by the source and is emitted by the field applicator may be a continuous or a pulsed electromagnetic alternating field, depending on the application. A pulsed DC voltage is also suitable. The pulse repetition frequency for this purpose is preferably in a range between 0.001 kHz and 300 kHz.

In addition to the antenna forms described above, a field applicator which has an antenna arrangement comprising one or more electrically conductive rods is also suitable for producing the electromagnetic field. These rods may in this case be arranged both parallel and at right angles to the running direction of the workpiece, in which case, in this context, the running direction is intended to mean the running direction of the workpiece at the point at which the workpiece is closest to the antenna arrangement.

Field applicators such as these are particularly suitable for the use of electromagnetic fields in the radio-frequency range. However, other frequency ranges may also be used in order to produce a plasma for plasma treatment. For example, microwaves may be used for producing and maintaining the plasma. Rod antennas, slot antenna elements or horn antenna elements are particularly suitable for use as field applicators for this purpose. Rectangular or round waveguides which are open for the emission of radiation at the end which points toward the workpiece may also advantageously be used.

In order to strengthen the electromagnetic field in the coating area, it is also advantageous for the coating area to be in the form of a rectangular or cylindrical resonator.

Irrespective of the frequency of the electromagnetic source which is used, a number of the radiating elements as mentioned above may be arranged one above the other and alongside one another, so that the apparatus can be used in a flexible manner for coating different body heights. By way of example, two or more radiating elements may in each case be connected to one electromagnetic source. These may be switched on or off, depending on the body height.

The plasma treatment according to the invention is particularly suitable for workpieces which have dielectric material parts. In particular, the invention provides for the treatment of workpieces with dielectric material parts composed of plastic, ceramic or glass.

As a result of the continuous coating process and the throughput rate associated with it, the apparatus is also particularly highly suitable for the coating of mass-produced articles, such as bottles which can in this way be provided, for example, with a diffusion barrier layer in a cost-effective manner.

Among other materials, plastic materials such as polycyclic hydrocarbons, polycarbonates, polyethylene therephthalates, polystyrene, polyethylene, in particular HDPE, polypropylene, polymethyl acrylate and PES have in this case been found to be suitable for the plasma coating process.

The apparatus can also be set up in order to treat internal surfaces or convex surfaces, for example for CVD coating of reflectors for halogen lamps or for the internal coating of bottles. For this purpose, the apparatus additionally has a device in order to shield a part of a workpiece, in particular the inner parts of a hollow or concave workpiece, in a gastight manner from the environment, forming a cavity. By way of example, a gastight cavity such as this would be formed from the inside of the reflector of a halogen radiating element and from a bottle, with the reflector being mounted on suitable seals of a transport unit of the transport device, in order to produce the cavity.

The cavity formed in this way may then be evacuated, by means of a suitable device, and filled with a gas which has the necessary composition for the intended plasma treatment.

The gas with which the cavity is filled may advantageously have a different composition form and be at a different pressure than the external environment, with the pressure in the cavity preferably being lower than the external pressure. The energy of the electromagnetic field which is emitted by the plasma generating device, and/or the pressure difference between the environment of the hollow body, can be set for pure internal coating such that plasma is produced only in the cavity, but not in the external area.

The parameters for producing a plasma and the parameters for the intensity of a plasma can also be influenced by suitable magnetic fields. A device is accordingly advantageous for producing a magnetic field in that part of the coating area in which the plasma burns. In particular, magnetic confinement such as this makes it possible when using low gas densities, in which case the free path lengths of the gas molecules associated with these low gas densities are long, to bound and to define the area in which the plasma is excited and maintained.

The transport device may also advantageously have individual transport units for holding the workpieces. These transport units are used for securing the workpieces and/or for sealing concave surfaces of the workpieces, for producing the necessary internal pressure, and for supplying the process gas for internal coatings.

In order to achieve particularly uniform coatings, the transport units may also rotate about one axis, so that the surface areas to be coated are subjected to a plasma intensity which is uniform when averaged over time.

A method for plasma treatment of workpieces is also provided within the scope of the invention. For this purpose, an electromagnetic field is produced in an area in order to excite a plasma within this area, with the workpiece then being treated by means of the plasma which is produced by the electromagnetic field, while the workpiece is being passed continuously through that area.

This method allows PECVD coatings to be produced, with the step of treatment of the workpiece for this purpose comprising the step of coating of the workpiece by plasma- pulse-induced vapor-phase deposition.

In addition to or as an alternative to PECVD coating, the method is also suitable for conditioning workpieces, in particular their surface, by means of the plasma. The process step of plasma conditioning of the workpiece is used for preparatory treatment of the surfaces for subsequent further processing. For example, the surface can be activated by introducing radicals. Such activation can be carried out, inter alia, by carrying out the plasma treatment in a gas atmosphere which includes oxygen.

For the internal coating of workpieces, for example for the coating of individual, in particular concave, surfaces, the step of treatment of the workpiece with a plasma comprises the step of producing the plasma in the interior of a cavity which is at least partially bounded by the workpiece.

The method according to the invention may also be used, in particular, to apply a diffusion barrier layer to the material parts. Diffusion barrier layers such as these are widely used, for example, for plastic bottles.

### BRIEF DESCRIPTION OF THE DRAWINGS

The invention will be described in more detail in the following text using, by way of example, preferred embodiments and with reference to the attached drawings, in which:

FIG. 1 shows a plan view of one embodiment of the coating apparatus according to the invention;

FIG. 2 shows a schematic view of a field applicator arrangement according to one embodiment of the coating apparatus according to the invention; and

FIG. 3 shows a schematic cross section through a further embodiment of the coating apparatus according to the invention.

### DETAILED DESCRIPTION OF THE INVENTION

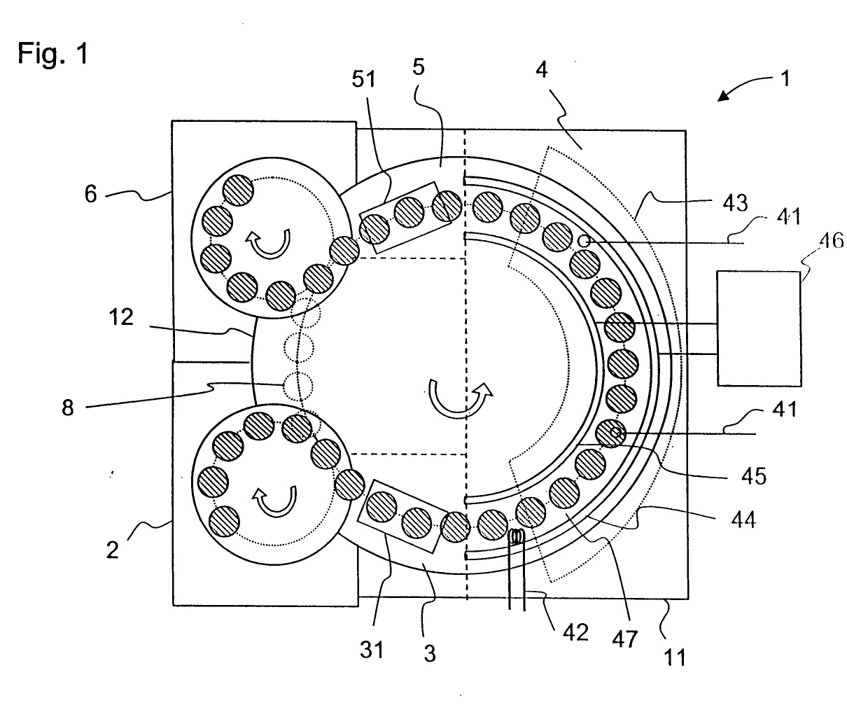

FIG. 1 shows a schematic plan view of an apparatus according to the invention for continuous plasma coating or plasma conditioning of dielectric bodies. The apparatus is preferably used for treating workpieces composed of plastic, ceramic or glass materials. The embodiment of the apparatus 1 shown in FIG. 1 is in the form of a circular feed.

The workpieces 9 to be treated are fed into the main chamber 11 of the apparatus via a feed section 2. The gas or the gas mixture for the plasma treatment is contained at a reduced pressure in the main chamber. Typical pressures for the plasma treatment are between 10⁻³ mBar and 1 mBar. During the process of feeding the workpieces 9 into the gas atmosphere, they are placed on transport segments 8 on a round feed table 12 and are then passed, on the rotating table 5, through various sections of the main chamber. In the process, the workpieces first of all enter a conditioning section 3. Preparatory treatments which are required for the plasma treatment are carried out in this section. For example, this section may contain a heater 31 which heats the workpieces to the temperature required for the plasma treatment. Other preparatory treatments may be the preparatory heating and/or conditioning by means of a plasma, as well as the cleaning and sterilization of the workpieces.

The rotation of the circular feed table 12 results in the workpieces 9 being passed through the coating section 4, after conditioning or preparation in the conditioning section. The major components of the coating section is a field applicator arrangement for electromagnetic energy, by means of which the ignited plasma is maintained. The embodiment of the field applicator arrangement shown in FIG. 1 comprises the antennas 44 and 45, which extend along a part of the path on which the workpieces are passed through the apparatus for continuous plasma coating. In the embodiment shown in FIG. 1, the antennas 44 and 45 are two concentric plates, which are in the form of an anode and cathode and between which the electromagnetic field extends in order to maintain the plasma.

A field which is produced by a source 46 is applied to the antennas 44 and 45. A radio-frequency electromagnetic alternating field, which may be pulsed or continuous, is in this case suitable for maintaining a plasma between the antennas. However, a supply with a pulsed DC voltage is likewise also possible, with the DC source preferably being pulsed in a frequency range between 1 Hz and 300 kHz.

An ignition apparatus 42 in the area of the antenna arrangement is used to ignite the plasma, which is then maintained further by the electromagnetic field between the antennas 44 and 45. The ignition apparatus may, for example, comprise an electrode or a pair of electrodes, to which a pulsed high voltage is applied. The electrode may be in the form of an incandescent wire, so that the gas is impact-ionized by the electrons which are emitted by incandescent emission from the incandescent wire and are accelerated by the high voltage that is applied.

Furthermore, sensors for monitoring the coating and the plasma can be arranged in the area of the coating section 4, in order to monitor the plasma coating or plasma conditioning process. Optical sensors for detecting the accompanying light emission from the plasma are suitable for this purpose, by way of example, in which case spectral analysis of the light also provides a conclusion about the gas composition and can provide parameters for process control. The layer thickness of the material which is deposited on the workpieces can also be monitored using optical sensors, for example by means of ellipsometric measurements.

Magnetic confinement of the plasma can be achieved by application of suitable magnetic fields. For example, as is shown in FIG. 1, a pair of sector magnets 43 can be used for this purpose, which are arranged above and below the circular feed table 12 and produce an axial field in the direction of the rotation axis of the table 12. Fields with magnetic field components in the transport direction, or in the radial direction at right angles to this, are likewise suitable, however.

After the coating section 4, the workpieces pass on the circular feed table 12 through a post treatment section 5. Processes for post treatment and preparation for the final outputting can be carried out in the post treatment section. For example, the post treatment section 5 may have cooling elements 51, by means of which the workpieces, which were previously heated in the conditioning section 3, are cooled down again so that it is possible to avoid major temperature stresses in the workpieces resulting from nonuniform cooling down in the denser atmosphere after being output.

Finally, the workpieces are passed to an output section 6, in which the workpieces are output from the main chamber 11.

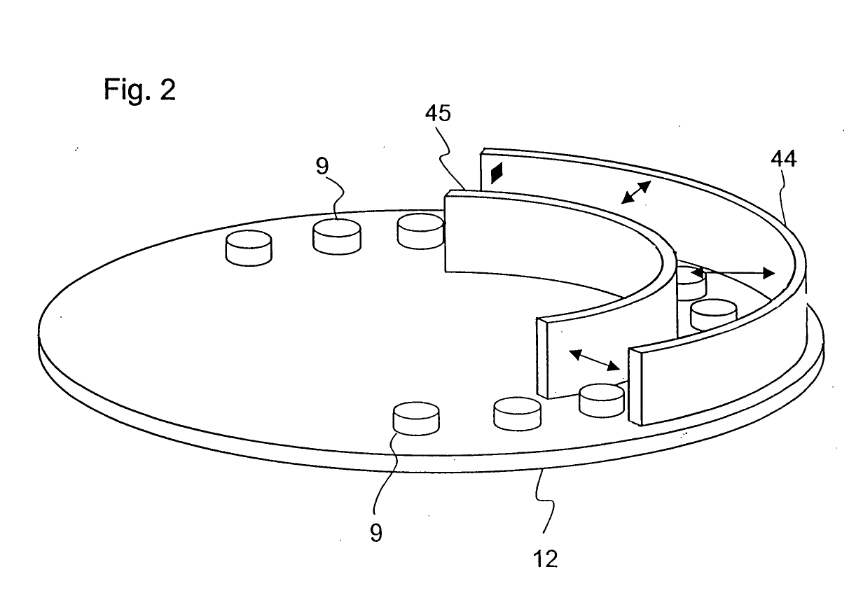

FIG. 2 shows a schematic view of the field applicator arrangement illustrated in FIG. 1. This embodiment of the field applicator arrangement has an antenna arrangement comprising two plates 44 and 45 which are bent in a circular shape and are spaced apart from one another in the radial direction.

The application of an electromagnetic alternating field to these plates results in an electrical alternating field which extends in the radial direction, as is indicated by the arrows.

The circular feed table 12 is arranged such that the workpieces 9 which are placed on the table are moved continuously on a circular path between the concentrically arranged plates and through the electromagnetic alternating field which is emitted by the plates.

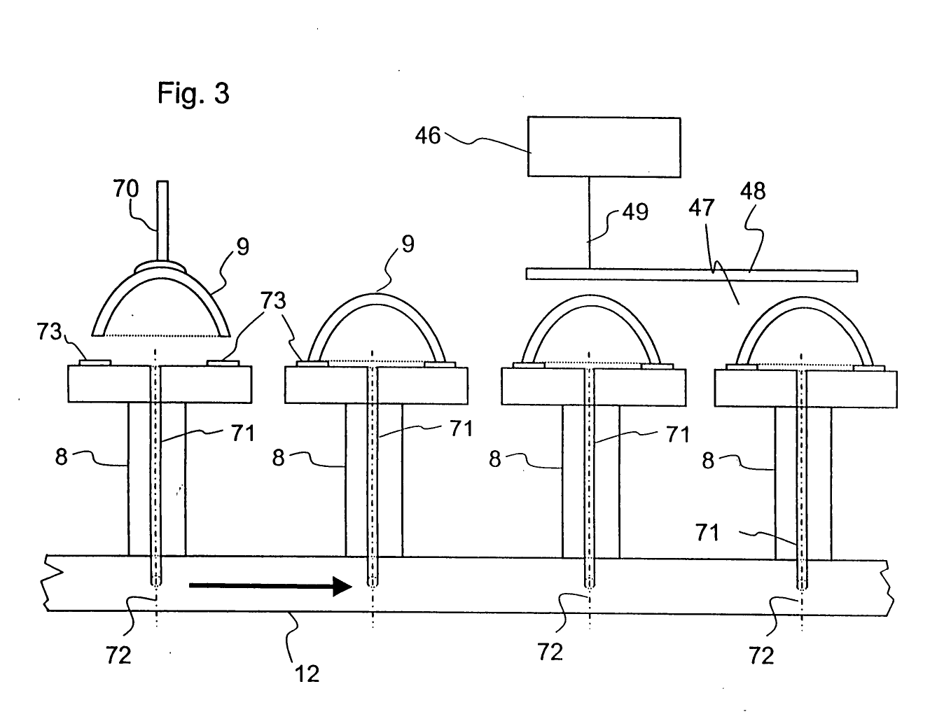

FIG. 3 shows a schematic cross section through another embodiment of the apparatus according to the invention for plasma treatment. The apparatus has a transport device 12. As in the embodiment described above, the transport device may have a circular feed table or else be in the form of a longitudinal feed for linear transport.

The apparatus, which is described by way of example with reference to FIG. 3, is particularly suitable for the internal coating of workpieces having hollow or concave surfaces, such as reflectors for halogen lamps. In particular, this apparatus also makes it possible to coat the interior of bottles. For example, the bottles can be provided with a diffusion barrier layer.

The hollow workpieces 9 are first of all placed by means of a placement device 20 on seals 73 of transport units 8 of the transport device 12, so that a cavity is produced which is partially bounded by the concave surface 91 of the workpiece 9 and shields the latter in a gastight manner from the environment.

The cavity can then be evacuated via a channel 71. A gas which is suitable for the CVD coating or surface conditioning can then be introduced via the channel. The gas pressure in the interior is in this case preferably less than the pressure in the environment, and is in the range between 10⁻³ mBar and 1 mBar.

In order to produce the plasma, the apparatus has a source 46 for electromagnetic energy, which is connected to an antenna arrangement via a suitable connection 49. In this example, the antenna arrangement comprises an electrically conductive rod 48 or a number of rods 48 arranged parallel. The rods in this exemplary embodiment are arranged parallel to the feed direction, which is indicated by the arrow in FIG. 3.

An electromagnetic field is produced in the area 47 between the transport device 12 and the antenna arrangement 48, by emission of the energy which is produced by the source 46. This field leads to a plasma being produced in the respective shielded cavities, in the cavity of the workpieces 9 which are located in this area during the transport process. However, the gas density is too great outside the workpieces and the free path length of the gas molecules associated with this is too short to overcome the ionization energy of the gas molecules by acceleration in the electromagnetic field. It is thus possible to carry out plasma internal treatment of the workpieces, such as producing a CVD coating on reflectors.

The transport units 8 are arranged on the transport device 12 such that they rotate about an axis 72. The workpieces 9 are thus rotated about their longitudinal axis during the coating process in the coating area 47. This compensates for nonuniform coatings which are caused by inhomogenities of the electromagnetic field in the coating region 47.

We claim:

1. A method for plasma treatment of workpieces, comprising the following steps:
production of an electromagnetic field within an area (47) in order to produce a plasma within this area,
treatment of a workpiece (9) by means of the plasma which is produced by the electromagnetic field,
distinguished by the workpiece being passed through the area (47) continuously.

2. The method as claimed in claim 1, in which the step of treatment of the workpiece (9) comprises the step of coating of the workpiece by plasma-pulse-induced vapor phase deposition.

3. The method as claimed in claim 1, in which the step of treatment of the workpiece (9) comprises the step of plasma conditioning of the workpiece.

4. The method as claimed in claim 3, in which the step of plasma conditioning comprises the step of plasma conditioning in a gas atmosphere which includes oxygen.

5. The method as claimed in claim 1, in which the step of treatment of the workpiece with a plasma comprises the step of producing the plasma in an interior of a hollow body which is at least partially bounded by the workpiece.

6. The method as claimed in claim 1, in which the step of treatment of the workpiece (9) comprises the step of rotation of the workpiece (9) about one axis (72).

7. The method as claimed in claim 1, in which the step of treatment of the workpiece comprises the step of coating a bottle.

8. The method as claimed in claim 7, in which the step of coating a bottle comprises the step of internally coating a bottle.
